(19) United States
(12) Patent Application Publication
(10) Pub. No.: US 2026/0020246 A1
(43) Pub. Date: Jan. 15, 2026

(54) SEMICONDUCTOR DEVICE AND METHOD OF MANUFACTURING THE SAME

(71) Applicant: Renesas Electronics Corporation, Tokyo (JP)

(72) Inventor: Shibun TSUDA, Tokyo (JP)

(21) Appl. No.: 19/253,216

(22) Filed: Jun. 27, 2025

(30) Foreign Application Priority Data
Jul. 11, 2024 (JP) 2024-111858

(51) Int. Cl. H10B 51/30; H10B 51/40

(52) U.S. Cl. CPC H10B 51/30; H10B 51/40

(57) ABSTRACT

A semiconductor device includes a selection transistor having a first paraelectric film, a ferroelectric film, a metal film, and a selection gate electrode that are formed on a semiconductor substrate in order, and a memory transistor having a second paraelectric film, the ferroelectric film, the metal film, and a memory gate electrode that are formed on the semiconductor substrate in order. A thickness of the first paraelectric film is larger than a thickness of the second paraelectric film. Each of the first and second paraelectric films contains nitrogen, and a nitrogen concentration in the first paraelectric film decreases toward a lower surface of the first paraelectric film from an upper surface of the first paraelectric film.

### CROSS-REFERENCE TO RELATED APPLICATIONS

The present application claims priority from Japanese Patent Application No. 2024-111858 filed on Jul. 11, 2024, the content of which is hereby incorporated by reference to this application.

### BACKGROUND

The present invention relates to a semiconductor device and a method of manufacturing the same, particularly, a semiconductor device having a ferroelectric memory cell and a method of manufacturing the semiconductor device.

There is disclosed a technique listed below. [Patent Document 1] Japanese Unexamined Patent Application Publication No. 2019-201172

As a semiconductor memory element that operates at a comparatively low voltage, a ferroelectric memory cell has been developed. The ferroelectric memory cell has a ferroelectric film formed on a semiconductor substrate, and a gate electrode formed on the ferroelectric film. By controlling a direction of polarization of the ferroelectric film, a state of the ferroelectric memory cell changes between a writing state on and an erasing state. Patent Document 1 discloses a structure and a manufacturing method of the ferroelectric memory cell.

### SUMMARY

In the ferroelectric memory cell, oxygen contained in the ferroelectric film may diffuse up to an upper surface of a semiconductor substrate. In this case, the oxygen and the upper surface of the semiconductor substrate react and an oxide film is formed, and this oxide film may degrade performance of the semiconductor device.

Other problems and novel features will be apparent from the present specification and the accompanying drawing.

An outline of a typical embodiment among embodiments disclosed in the present application will be briefly explained as follows.

In one embodiment, a semiconductor device has a selection transistor and a memory transistor. The selection transistor has a first paraelectric film, a first ferroelectric film, and a first gate electrode that are formed on a semiconductor substrate in order. The memory transistor has a second paraelectric film, a second ferroelectric film, and a second gate electrode that are formed on the semiconductor substrate in order. Here, a thickness of the first paraelectric film is larger than a thickness of the second paraelectric film. Each of the first and second paraelectric films contains nitrogen, and a nitrogen concentration in the first paraelectric film decreases toward a lower surface of the first paraelectric film from an upper surface of the first paraelectric film.

In one embodiment, a method of manufacturing a semiconductor device includes: forming a first paraelectric film on a semiconductor substrate; forming a second paraelectric film, which has a thickness smaller than that of the first paraelectric film, on the semiconductor substrate; introducing nitrogen into the first paraelectric film and the second paraelectric film by using a plasma nitriding method; forming a first ferroelectric film and a first gate electrode on the first paraelectric film in order, and forming a second ferroelectric film and a second gate electrode on the second paraelectric film in order; and forming a first source region and a first drain region in the semiconductor substrate.

According to one embodiment, the performance of the semiconductor device can be improved.

### BRIEF DESCRIPTION OF THE DRAWINGS

FIG. 1 is a planer layout of a semiconductor device according to an embodiment.

FIG. 2 is a cross-sectional view of the semiconductor device according to the embodiment.

FIG. 3 is a planer layout of the semiconductor device according to the present embodiment.

FIG. 4 is a graph showing an applied voltage at a time of each operation of a ferroelectric memory cell.

FIG. 5 is a cross-sectional view during a manufacturing step of the semiconductor device according to the embodiment.

FIG. 6 is a cross-sectional view during a manufacturing step of the semiconductor device according to the embodiment subsequent to FIG. 5.

FIG. 7 is a cross-sectional view during a manufacturing step of the semiconductor device according to the embodiment subsequent to FIG. 6.

FIG. 8 is a cross-sectional view during a manufacturing step of the semiconductor device according to the embodiment subsequent to FIG. 7.

FIG. 9 is a cross-sectional view during a manufacturing step of the semiconductor device according to the embodiment subsequent to FIG. 8.

FIG. 10 is a cross-sectional view during a manufacturing step of the semiconductor device according to the embodiment subsequent to FIG. 9.

FIG. is a cross-sectional view during a manufacturing step of the semiconductor device according to the embodiment subsequent to FIG. 10.

FIG. 12 is a cross-sectional view during a manufacturing step of the semiconductor device according to the embodiment subsequent to FIG. 11.

FIG. 13 is a cross-sectional view during a manufacturing step of the semiconductor device according to the embodiment subsequent to FIG. 12.

FIG. 14 is a cross-sectional view during a manufacturing step of the semiconductor device according to the embodiment subsequent to FIG. 13.

FIG. 15 is a cross-sectional view during a manufacturing step of the semiconductor device according to the embodiment subsequent to FIG. 14.

FIG. 16 is a cross-sectional view during a manufacturing step of the semiconductor device according to the embodiment subsequent to FIG. 15.

FIG. 17 is a cross-sectional view during a manufacturing step of the semiconductor device according to the embodiment subsequent to FIG. 16.

FIG. 18 is a cross-sectional view of a main part of the semiconductor device according to the embodiment.

FIG. 19 is a graph showing a concentration distribution of nitrogen introduced into an insulation film by a DNP method in a depth direction.

FIG. 20 is a graph showing current voltage characteristics of a memory transistor.

FIG. 21 is a cross-sectional view of a semiconductor device according to a modification example of the embodiment.

FIG. 22 is a cross-sectional view during a manufacturing step of the semiconductor device according to the modification example of the embodiment.

FIG. 23 is a graph showing current voltage characteristics of the memory transistor in which channel dose is performed.

FIG. 24 is a graph showing current voltage characteristics of the memory transistor in which no channel dose is performed.

FIG. 25 is a cross-sectional view of a main part of a semiconductor device according to a comparative example.

FIG. 26 is a cross-sectional view of a main part of the semiconductor device according to the comparative example.

### DETAILED DESCRIPTION

In the embodiments described below, the invention will be described by being divided into a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference characters throughout the drawings for describing the embodiments, and the repetitive description thereof will be omitted. In addition, the description of the same or similar portions is not repeated in principle unless particularly required in the following embodiments.

An X direction and a Y direction that are mentioned in the present application are along a main surface of a semiconductor substrate. The X direction and the Y direction are orthogonal to each other in plan view.

### EMBODIMENT

### Structure of Semiconductor Device

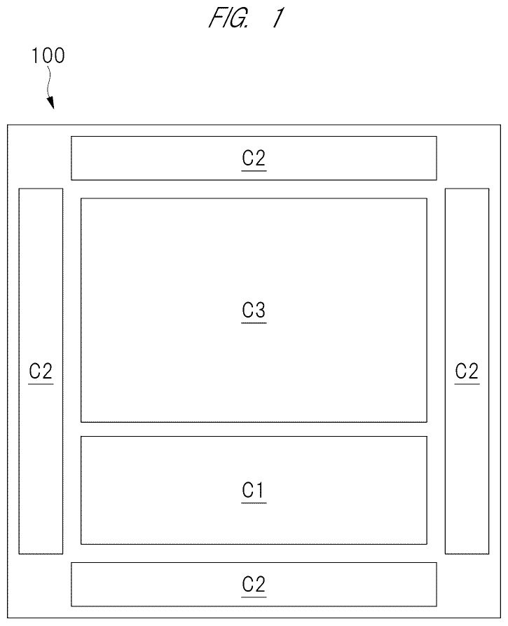

Hereinafter, by using FIG. 1 to FIG. 3, a semiconductor device 100 according to the present embodiment will be explained. The semiconductor device 100 has a ferroelectric memory cell MC as an electrically rewritable non-volatile memory cell.

FIG. 1 shows a planar layout of the semiconductor device 100 according to an embodiment. The semiconductor device 100 has a circuit region C1, a circuit region C2, and a circuit region C3.

The circuit region C1 has, for example, a logic circuit, which includes a CPU and a SRAM. A semiconductor element configuring a circuit included in the circuit region C1 is a low breakdown voltage MOSFET driven at a voltage of about 1.0 V. The circuit region C2 has, for example, an I/O circuit. A semiconductor element configuring a circuit included in the circuit region C2 is a high breakdown voltage MOSFET driven at a voltage of about 3.3 V. The circuit region C3 has a ferroelectric memory cell MC.

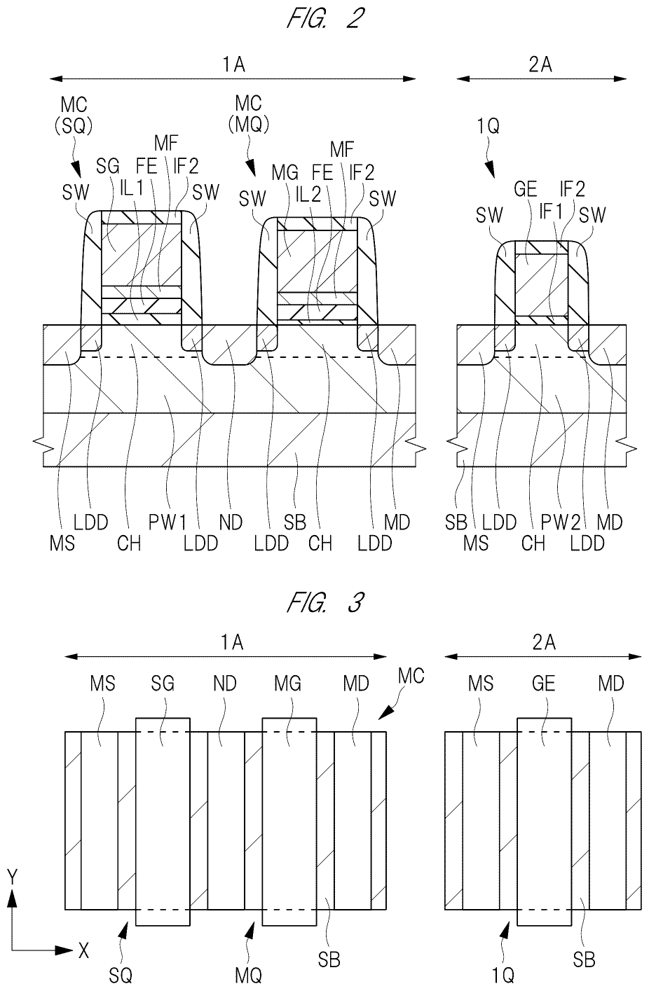

The semiconductor device 100 has a region 1A and a region 2A. FIG. 2 is a cross-sectional view showing the ferroelectric memory cell MC formed in the region 1A and a low breakdown voltage MOSFET 10 formed in the region 2A. FIG. 3 is a planer layout showing the ferroelectric memory cell MC and the low breakdown voltage MOSFET 1Q.

Hereinafter, the ferroelectric memory cell MC will be explained.

As shown in FIG. 2, the semiconductor substrate SB is made of, for example, p-type monocrystalline silicon (Si). In the region 1A, a p-type well region PW1 is formed in the semiconductor substrate SB.

The ferroelectric memory cell MC includes a selection transistor SQ and a memory transistor MQ. The selection transistor SQ includes a paraelectric film IL1, a ferroelectric film FE, a metal film MF, and a selection gate electrode SG. The selection transistor SQ selects the ferroelectric memory cell MC performing a writing operation, an erasing operation, and a reading operation. The memory transistor MQ has a Metal Ferroelectric Insulator Semiconductor (MFIS) structure that applies the ferroelectric film FE to a transistor. The memory transistor MQ includes a paraelectric film IL2, a ferroelectric film FE, a metal film MF, and a memory gate electrode MG.

In a well region PW1, a channel region CH that is a p-type semiconductor region is formed. The channel region CH has a higher impurity concentration than an impurity concentration of the well region PW1. In FIG. 3, a lower end of the channel region CH is illustrated by dotted lines. The channel region CH has a predetermine depth from the upper surface of the semiconductor substrate SB halfway through the semiconductor substrate SB (well region PW1). The channel region CH is formed directly under each of the selection gate electrode SG and the memory gate electrode MG.

The paraelectric film IL1 and the paraelectric film IL2 are formed on the semiconductor substrate SB including the well region PW1. The paraelectric film IL1 and the paraelectric film IL2 are, for example, silicon oxide films. The paraelectric film IL1 is larger in thickness than the paraelectric film IL2. This reason is to prevent the polarization in the ferroelectric film FE of the selection transistor SQ from occurring. The paraelectric film IL1 has a thickness of, for example, 6 nm or more. The paraelectric film IL2 has a thickness of, for example, 1 nm or more.

The ferroelectric film FE is formed on each of the paraelectric film IL1 and the paraelectric film IL2. The ferroelectric film FE is made of a metal film and is, for example, a high dielectric constant film having higher in dielectric constant than a silicon nitride film. A thickness of the ferroelectric film FE is, for example, 4 nm or more and 20 nm or less.

The ferroelectric film FE in the present embodiment is configured by, for example, a material containing a metal oxide and a first element. The metal oxide is, for example, hafnium oxide (HfO₂), gallium oxide (Ga₂ O₃), or the like. The first element is, for example, zirconium (Zr). The first element may be silicon (Si), nitrogen (N), yttrium (Y), germanium (Ge), lanthanum (La), or ytterbium (yb) instead of zirconium.

The metal film MF is formed on the ferroelectric film FE. The metal film MF is made of, for example, a titanium nitride film, a tantalum nitride film, or a tungsten film. A thickness of the metal film is, for example, 2 nm or more and 20 nm or less.

The metal film MF is used for applying a stress to the ferroelectric film FE during a manufacturing step of the ferroelectric film FE and for controlling an orientation of crystals of the ferroelectric film FE. Accordingly, after forming the metal fill MF, the metal film MF may be removed. However, by removing the metal film MF, characteristics of the metal film MF may vary. For this reason, it is preferable to leave the metal film MF. Note that when the metal film MF is left, the metal film MF of the selection transistor SQ functions as a portion of the selection gate electrode SG described below. In addition, when the metal film MF is left, the metal film MF of the memory transistor MQ functions as a portion of the memory gate electrode MG described later.

The selection gate electrode SG is formed on the metal film MF arranged on the paraelectric film IL1. The selection gate electrode SG is made of, for example, a polycrystalline silicon film into which n-type impurities are introduced. In addition, an insulation film IF2 is formed on the selection gate electrode SG. On a side surface of the selection gate electrode SG, a sidewall spacer SW is formed. The sidewall spacer SW is made of, for example, a silicon oxide film and a silicon nitride film formed on the silicon oxide film. In this way, the selection transistor sQ has a first lamination body that includes the paraelectric film IL1 on the semiconductor substrate SB, the ferroelectric film FE on the paraelectric film IL1, the metal film MF on the ferroelectric film FE, and the selection gate electrode SG on the metal film MF. The first lamination body may have the insulation film IF2 on the selection gate electrode SG. The insulation film IF2 is made of, for example, a silicon nitride film.

The memory gate electrode MG is formed on the metal film MF arranged on the paraelectric film IL2. The memory gate electrode MG is made of, for example, a polycrystalline silicon film into which n-type impurities are introduced. In addition, the insulation film IF2 is formed on the memory gate electrode MG. On a side surface of the memory gate electrode MG, the sidewall spacer SW is formed. In this way, the memory transistor MQ has a second lamination body that includes the paraelectric film IL2 on the semiconductor substrate SB, the ferroelectric film FE on the paraelectric film IL2, the metal film MF on the ferroelectric film FE, and the memory gate electrode MG on the metal film MF. The second lamination body may have the insulation film IF2 on the memory gate electrode MG. The insulation film IF2 is made of, for example, a silicon nitride film.

A low concentration region LDD that is an n-type impurity region having a low concentration is formed in the semiconductor substrate SB, and is located under the sidewall spacer SW. In addition, a diffusion region ND that is the n-type impurity region, a source region MS, and a drain region MD are formed in the semiconductor substrate SB (in the well region PW1) exposed from the sidewall spacer SW. Each impurity concentration of the diffusion region ND, the source region MS, and the drain region MD is higher than an impurity concentration of the low concentration region LDD. The low concentration region LDD and the drain region MD are connected to each other, and each of the low concentration region LDD and the drain region MD configures a portion of the drain region of the ferroelectric memory cell MC. In addition, the low concentration region LDD and the source region MS are connected to each other, and each of the low concentration region LDD and the source region MS configures a portion of the source region MS of the ferroelectric memory cell MC. The channel region CH is arranged between the source region MS and the drain region MD.

FIG. 3 shows the semiconductor substrate SB, the selection gate electrode SG, the memory gate electrode MG, the gate electrode GE, the diffusion region ND, the source region MS, and the drain region MD. In FIG. 3, hatchings are denoted at portions at which the semiconductor substrate SB is not overlapped with the selection gate electrode SG, the memory gate electrode MG, the gate electrode GE, the diffusion region ND, the source region MS, and the drain region MD.

As shown in FIG. 3, the selection gate electrode SG extends in the Y direction. In addition, the memory gate electrode MG extends in the Y direction. Further, the diffusion region ND, the source region MS, and the drain region MD also extend in the Y direction. In plan view, the source region MS, the selection gate electrode SG, the diffusion region ND, the memory gate electrode MG, and the drain region MD are arranged in the X direction in order. In other words, in plan view, the first lamination body and the second lamination body are both arranged between the source region MS and the drain region MD.

As shown in FIG. 3, the low concentration region LDD and the diffusion region ND that are formed directly under the region between the selection gate electrode SG and the memory gate electrode MG are connected to each other. By the low concentration region LDD and the diffusion region ND, the memory transistor MQ and the selection transistor SQ are electrically connected to each other.

Note that although not illustrated here, a silicide layer may be formed on the selection gate electrode SG, the memory gate electrode MG, the diffusion region ND, the source region MS, and the drain region MD. Note that the silicide layer is made of, for example, cobalt silicide, nickel silicide, nickel platina silicide, or the like.

The first lamination body, the source region MS, and the drain region MD configure the selection transistor SQ. The second lamination body, the source region MS, and the drain region MD configure the memory transistor MQ. The first lamination body, the second lamination body, the source region MS, and the drain region MD configure the ferroelectric memory cell MC.

Here, each of the paraelectric film IL1 and the paraelectric film IL2 contains nitrogen. Namely, each of the paraelectric film IL1 and the paraelectric film IL2 is a silicon oxide film into which nitrogen is introduced. A nitrogen concentration in the paraelectric film IL1 decreases toward the lower surface of the paraelectric film IL1 from the upper surface of the paraelectric film IL1. Namely, the nitrogen concentration in the paraelectric film IL1 becomes highest in the vicinity of the upper surface of the paraelectric film IL1. In addition, a nitrogen concentration in the paraelectric film IL2 is almost constant in a depth direction in the paraelectric film IL1. However, the nitrogen concentration in the paraelectric film IL2 may decrease low toward the lower surface of the paraelectric film IL1 from the upper surface of the paraelectric film IL1.

The nitrogen concentration in the paraelectric film IL1 in the vicinity of the upper surface of the paraelectric film IL1, and the nitrogen concentration in the paraelectric film IL2 in the vicinity of the upper surface of the paraelectric film IL2 are almost equal to each other. In contrast, the nitrogen concentration in the paraelectric film IL1 in the vicinity of the lower surface of the paraelectric film IL1 is lower than the nitrogen concentration in the paraelectric film IL2 in the vicinity of the lower surface of the paraelectric film IL2.

Next, the low breakdown voltage MOSFET 1Q will be explained.

In the region 2A, a p-type well region PW2 is formed in the semiconductor substrate SB. The low breakdown voltage MOSFET 1Q includes the gate insulation film IF1 and the gate electrode GE.

In the well region PW2, a channel region CH that is a p-type semiconductor region is formed. The channel region CH has a higher impurity concentration than that of the well region PW1. The channel region CH has a predetermine depth from the upper surface of the semiconductor substrate SB halfway through the semiconductor substrate SB (well region PW2). The channel region CH is formed directly under the gate electrode GE.

The gate insulation film IF1 is, for example, a silicon oxide film. A thickness of the gate insulation film IF1 is larger than the thickness of the paraelectric film IL2. The gate electrode GE is made of, for example, a polycrystalline silicon film into which n-type impurities are introduced. In addition, an insulation film IF2 is formed on the gate electrode GE. On a side surface of the gate electrode GE, a sidewall spacer SW is formed.

The low concentration region LDD that is an n-type impurity region having a low concentration is formed in the semiconductor substrate SB, and is located under the sidewall spacer SW. In addition, the source region MS and the drain region MD that are n-type impurity regions are formed in the semiconductor substrate SB (well region PW2) exposed from the sidewall spacer SW. Each impurity concentration of the source region MS and the drain region MD is higher than the impurity concentration of the low concentration region LDD. The low concentration region LDD and the drain region MD are connected to each other, and each of the low concentration region LDD and the drain region MD configures a portion of the drain region of the low breakdown voltage MOSFET 1Q. In addition, the low concentration region LDD and the source region MS are connected to each other, and each of the low concentration region LDD and the source region MS configures a portion of the source region of the low breakdown voltage MOSFET 1Q. The channel region CH is arranged between the source region MS and the drain region MD. As shown in FIG. 3, the gate insulation film IF1 and the gate insulation film IF2 are arranged between the source region MS and the drain region MD in plan view.

The source region MS, the drain region MD, the gate insulation film IL1, and the gate electrode GE configure the low breakdown voltage MOSFET 1Q. The gate insulation film IF1 contains nitrogen, and the nitrogen concentration in the gate insulation film is IF1 lower than the nitrogen concentration in the paraelectric film IL2.

### Operation of Ferroelectric Memory Cell MC

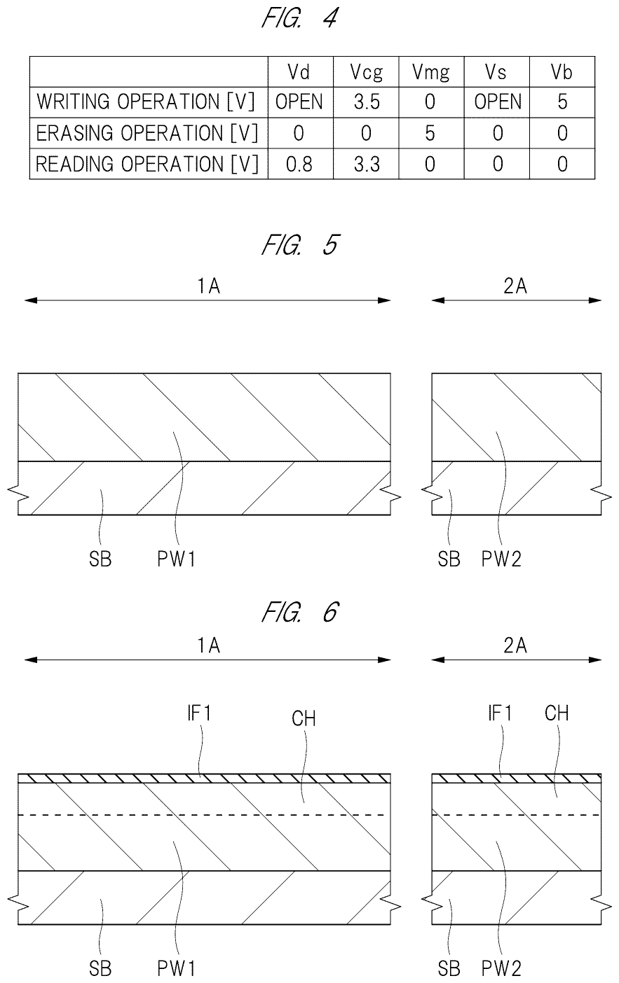

At a time of each operation of the ferroelectric memory cell MC, a voltage shown by FIG. 4 is applied. A voltage Vmg is applied to the memory gate electrode MG, and a voltage Vcg is applied to the selection gate electrode SG. A voltage Vs is applied to the source region MC, and a voltage Vd is applied to the drain region MD, and a voltage Vb is applied to the well region PW1. Here, the operation of the selected ferroelectric memory cell MC will be explained.

In a writing operation, a voltage indicated by a column of “WRITING OPERATION” shown by FIG. 4 is applied to the ferroelectric memory cell MC. Consequently, positive residual polarization is left in the ferroelectric film FE the memory transistor MQ, and a direction of the of polarization turns upward. As a result, a threshold voltage of the memory transistor MQ rises, and the ferroelectric memory cell MC becomes a writing state until its erasing operation is performed.

In an erasing operation, a voltage indicated by a column of “ERASING OPERATION” shown by FIG. 4 is applied to the ferroelectric memory cell MC. Consequently, negative residual polarization is left in the ferroelectric film FE of the memory transistor MQ, and a direction of the polarization turns downward. As a result, a threshold voltage of the memory transistor MQ drops, and the ferroelectric memory cell MC becomes an erasing state until its writing operation is performed.

In a reading operation, a voltage indicated by a column of “READING OPERATION” shown by FIG. 4 is applied to the ferroelectric memory cell MC. The voltage applied to the memory gate electrode MG at the time of the reading operation is set so as to become lower than the threshold value of the memory transistor MQ on the writing state and to become higher than the threshold value of the memory transistor MQ on the erasing state. Consequently, in the ferroelectric memory cell MC on the writing state, no current flows or a comparatively low current flows. In contrast, in the ferroelectric memory cell MC on the erasing state, a comparatively large current flows. In this way, based on magnitude of a current value flowing in the ferroelectric memory cell MC, a memory state of the ferroelectric memory cell MC can be determined.

Here, by forming the paraelectric film IL2 having smaller in thickness than the paraelectric film IL1, the polarization easily occurs in the ferroelectric film FE of the memory transistor MQ. In addition, the selection transistor SQ has the ferroelectric film FE, but the selection transistor SQ is a selection element, but not a memory element. When the polarization occurs in the ferroelectric film FE of the selection transistor SQ, the selection transistor SQ cannot be controlled, so that it is required to prevent the occurrence of the polarization in the ferroelectric film FE of the selection transistor SQ. Here, by forming the paraelectric film IL1 that is larger in thickness than the paraelectric film IL2, the polarization is prevented from occurring in the ferroelectric film FE of the selection transistor so by an influence of an electric field.

### Method of Manufacturing Semiconductor Device

Hereinafter, by using FIG. 5 to FIG. 17, a method of manufacturing the semiconductor device according to the present embodiment will be explained. In FIG. 5 to FIG. 17, the region 1A is illustrated on a left side, and the region 2A is illustrated on a right side. Note that illustration and explanation of a method of manufacturing the high breakdown voltage MOSFET in the circuit region 2C shown by FIG. 1 will be omitted.

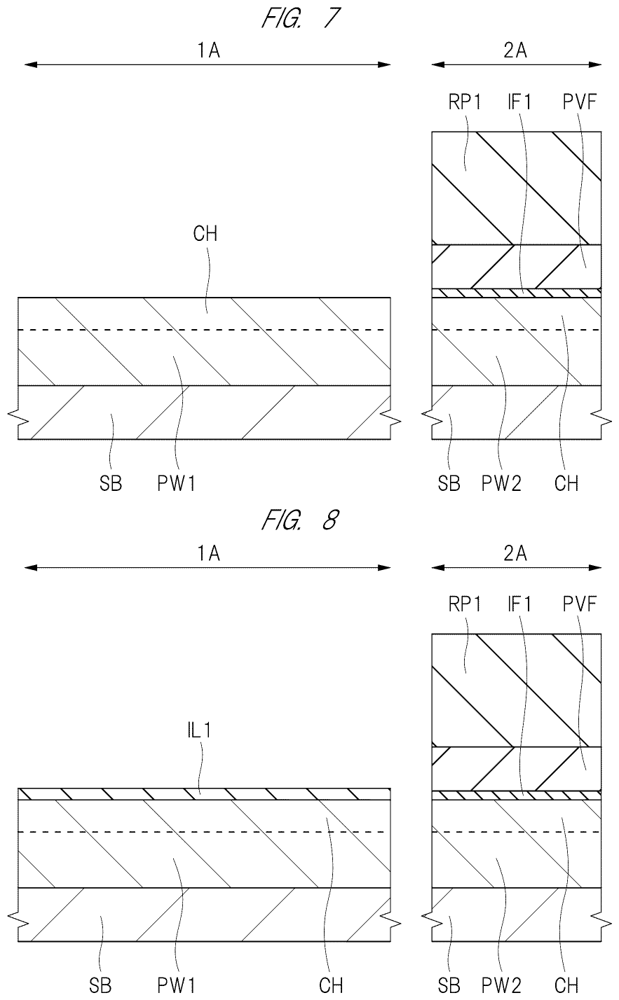

Firstly, as shown in FIG. 6, the semiconductor substrate SB made of, for example, monocrystalline silicon into which p-type impurities are introduced is prepared. Next, by a photolithography technique and an ion implantation method, the well region PW1 is formed in the semiconductor substrate SB in the region 1A, and the well region 2A is formed in the semiconductor substrate SB in the region 2A. The well region PW1 and the well region PW2 are formed up to a predetermined depth from the upper surface of the semiconductor substrate SB.

Next, as shown in FIG. 6, by implanting p-type impurities by the ion implantation method into the semiconductor substrate SB, the channel regions CH that are p-type impurity regions are formed in the semiconductor substrate SB in the region 1A and the region 2A. A depth of the channel region CH is shallower than each depth of the well region PW1 and the well region PW2.

Next, by a thermal oxidation method, the gate insulation film IF1 is formed on the semiconductor substrate SB in the region 1A and the region 2A. Next, by using a Decoupled Plasma Nitridation (DPN) method, nitrogen is introduced into the gate insulation film IF1. Power (energy) used for nitrogen introduction by the DPN method (plasma nitridation method) here is, for example, 200 W or more and 300 W or less.

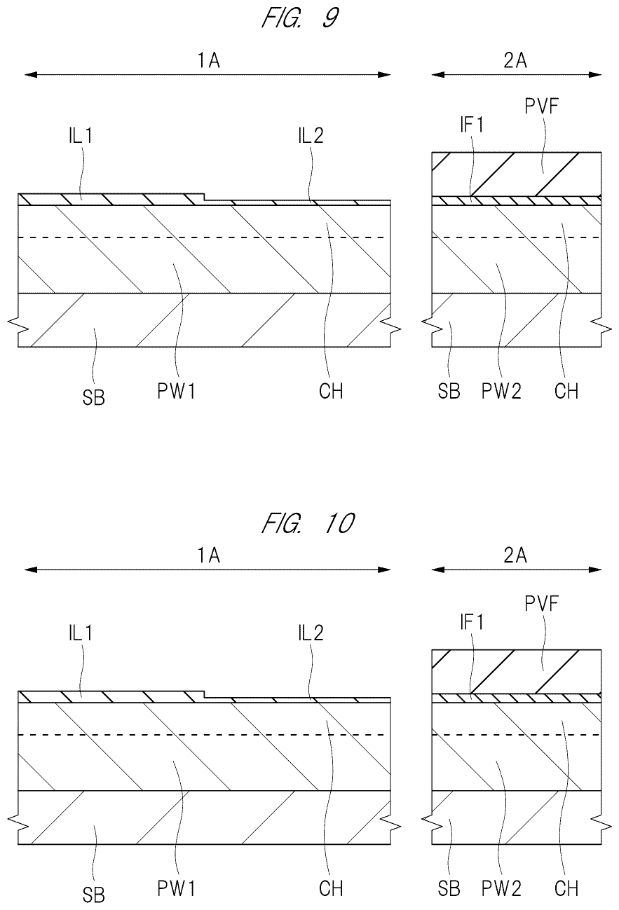

Next, as shown in FIG. 7, a protection film PVF is formed on the gate insulation film IF1 in the region 2A, and the gate insulation film IF1 formed in the region 1A is removed. Firstly, for example by a Chemical Vapor Deposition (CVD) method, the protection film PVF is formed on the gate insulation film IF1 formed in the region 1A and the region 2A. The protection film PVF is, for example, a polycrystalline silicon film. In addition, a thickness of the protection film PVF is, for example, 20 nm or more and 50 nm or less. Next, a resist pattern RP1 opening the region 1A is formed on the protection film PVF. Then, by performing an etching process using the resist pattern RP1 as a mask, the protection film PVF and the gate insulation film IF1 that are formed in the region 1A is selectively removed. After the etching process, the protection film PVF and the gate insulation film IF are left on the semiconductor substrate SB in the region 2A.

Here, when the protection film PVF is a polycrystalline silicon film, the etching process is performed by a dry etching process. The etching process with respect to the gate insulation film IF1 is performed by, for example, a wet etching process using a solution containing hydrofluoric acid.

Next, as shown in FIG. 8, for example by a thermal oxidation method, the paraelectric film IL1 is formed on the semiconductor substrate SB in the region 1A. The paraelectric film IL1 is formed of, for example, a silicon oxide film.

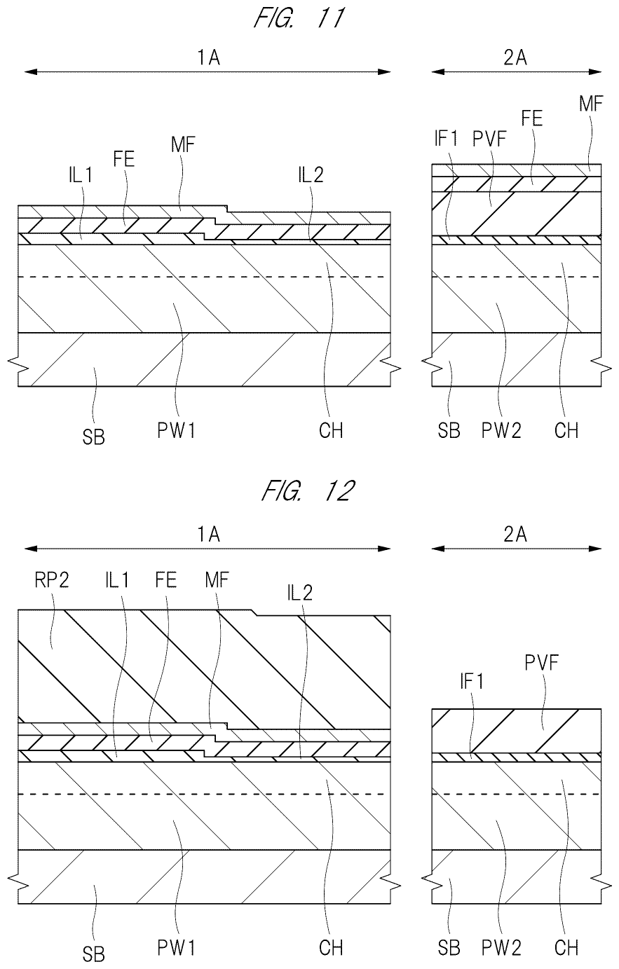

Next, as shown in FIG. 9, the resist pattern RP1 is removed by the ashing process. A resist pattern (not shown) that opens the region 2A and a portion of the region 1A is formed on the paraelectric film IL1. The resist pattern covers a region for forming the selection transistor SQ in the region 1A, and exposes a region for forming the memory transistor SQ. Next, by performing the etching process using the resist pattern as a mask, the paraelectric film IL1 exposed from the resist pattern is removed, and the upper surface of the semiconductor substrate SB is exposed. Then, by removing the resist pattern by the ashing process, the paraelectric film IL1 is exposed. Next, for example by the thermal oxidation method, the paraelectric film IL2 is formed on the semiconductor substrate SB exposed from the paraelectric film IL1 in the region 1A. The thickness of the paraelectric film IL2 is smaller than both of the thickness of the paraelectric film IL1 and the thickness of the gate insulation film IF1. In this way, the paraelectric film IL1 and the paraelectric film IL2 that mutually have a different thickness are formed in the region 1A.

Next, as shown in FIG. 10, by using the DPN method, nitrogen is introduced into the paraelectric film IL1 and the paraelectric film IL2. Power used for the nitrogen introduction by the DPN method here is, for example, 90 W or more and 300 W or less. However, power used for a plasma nitriding method with respect to the paraelectric film IL1 and the paraelectric film IL2 is larger than the power used for the plasma nitriding method with respect to the gate insulation film IF1 that is explained by using FIG. 6. In this way, in the present embodiment, an amount of nitrogen introduced into the paraelectric film and the IL1 paraelectric film IL2 is set so as to become higher than an amount of nitrogen introduced into the gate insulation film IF1 that is explained by using FIG. 6. This is because when the amount of nitrogen introduced into the gate insulation film IF1 is excessively high, mobility of electrons in the low breakdown voltage MOSFET 10 decreases. Specifically, when the power used for the plasma nitriding method in a step explained by using FIG. 6 is made equally high to the power used for the plasma nitriding method in a step explained by using FIG. 10, the nitrogen passes through the gate insulation film IF1 and easily reaches at the upper surface of the semiconductor substrate SB. As a result, the mobility of electrons drops by the upper surface of the semiconductor substrate SB being damaged, so that it is required to suppress the amount of nitrogen introduced into the gate insulation film IF1.

In contrast, considering a drop of the electric field applied to the ferroelectric film FE (see FIG. 3) and a reduction in a shift width of a threshold voltage due an increase in the thickness of the paraelectric film IL2, the power used for the plasma nitriding explained by using FIG. 10 is preferably smaller than the power used for the plasma nitriding explained by using FIG. 10. The shift width of the threshold voltage is a width of a hysteresis curve indicated by characteristics (current voltage characteristics) of a drain current with respect to a gate voltage in the selection transistor SQ. A current voltage curve measured by increasing the gate voltage from negative to positive and a current voltage curve measured by from positive to negative decreasing the gate voltage indicate loci different from each other. Namely, those current voltage curves draw hysteresis curves. From this point, it is understood that the threshold voltages of the selection transistor SQ are different in a case of increasing the gate voltage from negative to positive and a case of decreasing the gate voltage from positive to negative. A difference between those threshold voltages is the shift width (memory window) of the threshold voltage.

Next, as shown in FIG. 11, an amorphous film is formed on the protection film PVF formed in the region 2A and on the paraelectric film IL1 and the paraelectric film IL2 formed in the region 1A. The amorphous film can be formed by, for example, an Atomic Layer Deposition (ALD) method. The amorphous film is made of, for example, the material containing the metal oxide and the first element. The metal oxide is, for example, hafnium oxide (HfO₂), gallium oxide (Ga₂ O₃), or the like. The first element is, for example, zirconium (Zr). The first element may be silicon (Si), nitrogen (N), yttrium (Y), germanium (Ge), lanthanum (La), or ytterbium (yb) instead of zirconium.

Next, for example by the CVD method, the metal film MF is formed on the amorphous film in the region 1A and the region 2A.

Next, by performing a thermal process, the amorphous film is crystalized, and the ferroelectric film FE is formed. The thermal process is performed at a temperature of 600 degrees Celsius less by a Rapid Thermal Annealing (RTA) method. The above thermal process may be performed by using a microwave of a frequency of 1 GHz or more and 10 GHZ or less, or by using a microwave of a frequency of 2.45 GHZ. The thermal process using the microwave can crystallize at a lower temperature than that of a lamp heating process, and can be performed at a temperature of, for example, 400 degrees Celsius or less.

In addition, in this crystallization step, the orientation of the ferroelectric film FE is controlled by the stress from the metal film MF. That is, when the amorphous film is crystallized to the ferroelectric film FE, the metal film MF has a function to orientate a crystal phase of the ferroelectric film FE in a rectangular crystal.

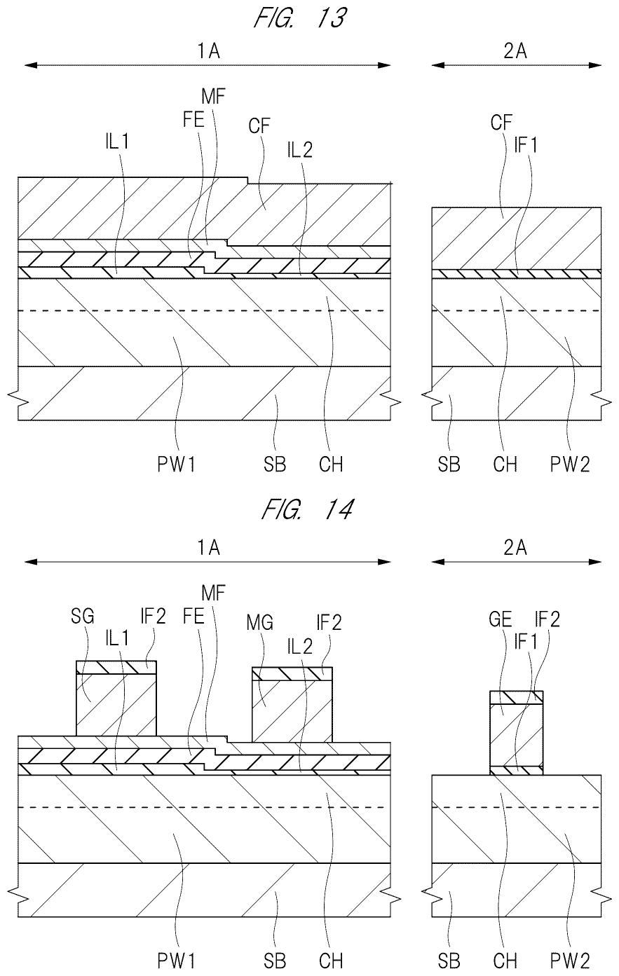

Next, as shown in FIG. 12, a resist pattern RP2 opening the region 2A is formed on the metal film MF formed in the region 1A. Then, the dry etching process is performed by using the resist pattern PR2 as a mask. Consequently, the metal film MF and the ferroelectric film FE that are formed in the region 2A are selectively removed.

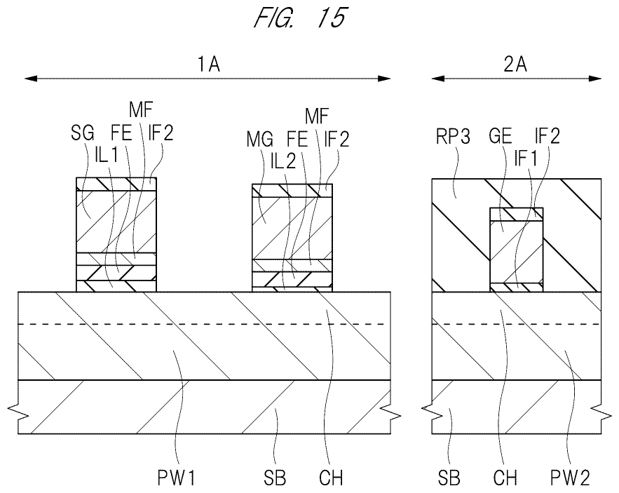

Next, as shown in FIG. 13, the resist pattern RP2 is removed by the ashing process. Then, for example by the CVD method, a conductive film CF is formed on the metal film MF formed in the region 1A and on the protection film PVF formed in the region 2A. The conductive film CF is, for example, a polycrystalline silicon film into which n-type impurities are introduced. A thickness of the conductive film CF is, for example, 95 nm. In FIG. 13, the protection film PVF and the polycrystalline silicon film formed on the protective film PVF are integrated, and are illustrated as the conductive film CF. The polycrystalline silicon film may be crystallized by performing the thermal process to the amorphous film after forming the amorphous film and may be formed. Next, the n-type impurities are introduced into the conductive film CF by the ion implantation method.

Next, as shown in FIG. 14, for example by the CVD method, the insulation film IL2 is formed on the conductive film CF. The insulation film IF2 is made of, for example, a silicon nitride film. Then, by performing the dry etching process using the resist pattern (not shown) as a mask, the insulation film IF2 is patterned. Consequently, a part of each of the insulation film IF2 in the region 1A and the insulation film IF2 in the region 2A are removed, and an upper surface that is a part of the conductive film CF is exposed. Next, after removing the resist pattern by the ashing process, the dry etching process is performed by using the insulation film IF2 as a mask, thereby removing a part of the conductive film CF.

In this way, by patterning the conductive film CF, the selection gate electrode SG is formed on the metal film MF in the region 1A, the memory gate electrode MG is formed on the metal film MF in the region 1A, and the gate electrode GE is formed on the gate insulation film IF1 in the region 2A. The selection gate electrode SG is formed at a position overlapping with the paraelectric film IL1 in plan view, and the memory gate electrode MG is formed at a position overlapping with the paraelectric film IL2 in plan view.

Next, as shown in FIG. 15, a resist pattern that covers the semiconductor substrate SB, the gate insulation film IF1, and the gate electrode GE in the region 2A and that opens the region 1A. Then, the dry etching process is performed in a state in which the gate electrode GE, the semiconductor substrate SB, and the gate insulation film IF1 in the region 2A are covered with the resist pattern RP3. Namely, the metal film MF and the ferroelectric film FE that are exposed from the selection gate electrode SG and the memory gate electrode MG in the region 1A are removed. In this time, the thickness of the paraelectric film IL1 and the thickness of the paraelectric film IL2 in the region 1A decrease by the above dry etching process. As a result, the semiconductor substrate SB may be exposed or not be exposed. Here, a case in which the semiconductor substrate SB is exposed will be explained.

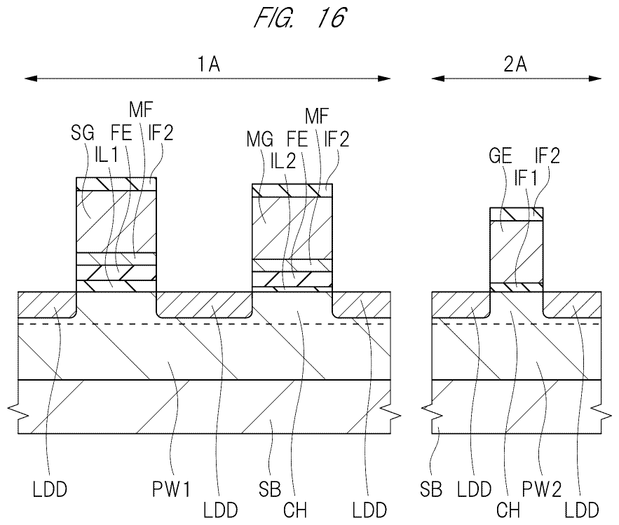

Next, as shown in FIG. 16, the resist pattern RP3 is removed by the ashing process. Then, the low concentration region LDD is formed in the semiconductor substrate SB exposed from the gate electrode GE, the selection gate electrode SG, and the memory gate electrode MG by the ion implantation method.

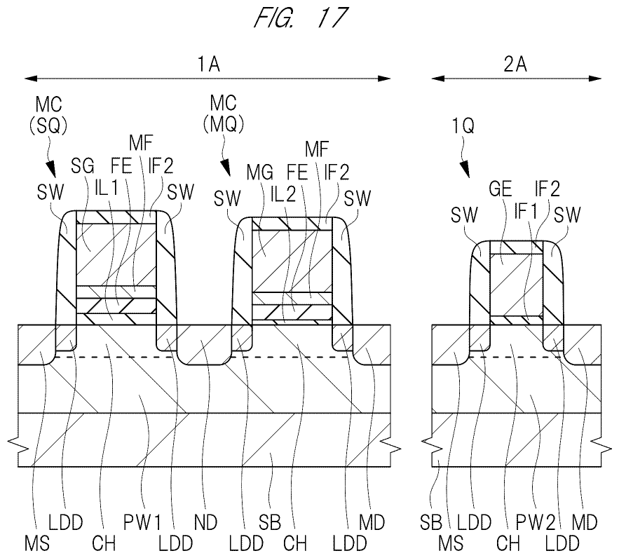

Next, as shown in FIG. 17, a lamination film including, for example, the silicon oxide film and the silicon nitride film is formed on the insulation film IF2 and on the semiconductor substrate SB by, for example, the CVD method so as to cover the gate electrode GE, the selection gate electrode SG, and the memory gate electrode MG. Then, by an anisotropic etching process, the silicon oxide film and the silicon nitride film are processed. Consequently, on the side surface of each of the gate electrode GE, the selection gate electrode SG, and the memory gate electrode MG, the sidewall spacer SW made of the above lamination film is formed.

Next, in the semiconductor substrate SB exposed from the sidewall spacer SW in the region 1A and the region 2A, the diffusion region ND, the source region MS, and the drain region MD are formed by the photolithography technique and the ion implantation method. In the region 1A, the diffusion region ND, the source region MS, and the drain region MD are formed in the well region PW2. In the region 2A, the source region MS and the drain region MD are formed in the well region PW2. Here, in plan view, the source region MS and the drain region MD are formed in the semiconductor substrate SB so that the selection gate electrode SG and the memory gate electrode MG are arranged between the source region MS and the drain region MD.

Thereafter, if necessary, the silicide layer may be formed on the gate electrode GE, the selection gate electrode SG, the memory gate electrode MG, the diffusion region ND, the source region MS, and the drain region MD. The silicide layer can be formed by a Self Aligned Silicide (silicide) technique, and is made of, for example, cobalt silicide, nickel silicide, or nickel platina silicide. As described above, the semiconductor device including the low breakdown voltage MOSFET 10 and the ferroelectric memory cell MC is manufactured.

### Effects of Present Embodiment

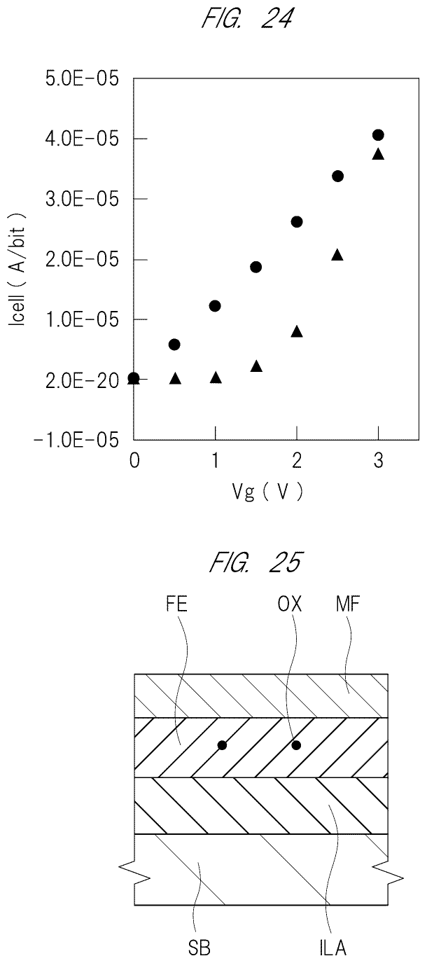

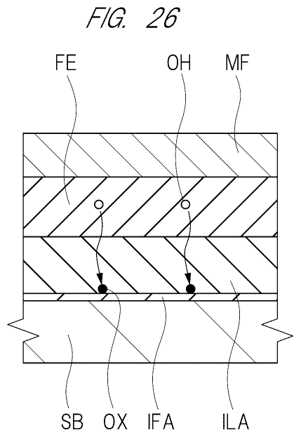

Each of FIG. 25 and FIG. 26 shows a cross-sectional view of a main part of a semiconductor device according to comparative example.

As shown in FIG. 25 and FIG. 26, in a semiconductor device according to a comparative example, a paraelectric film ILA, a ferroelectric film FE, and a metal film MF are formed in order. However, here, the comparative example is different from the present embodiment in that nitrogen is not introduced into the paraelectric film ILA.

As shown in FIG. 25, during a manufacturing step of the ferroelectric memory cell, the ferroelectric film FE contains oxygen OX. As shown in FIG. 26, this oxygen OX moves toward the semiconductor substrate SB by the thermal process performed during the manufacturing step of the semiconductor device. The thermal process is, for example, a thermal process performed during formation of the gate electrode, a thermal process performed during formation of the source region and the drain region, or the like. The moved oxygen OX reacts with silicon on a surface of the semiconductor substrate SB, and an oxide film IFA as shown by FIG. 26 is formed.

In this case, an oxygen vacancy OH occurs at a position where the oxygen OX exists in the ferroelectric film FE. The oxygen vacancy OH decreases performance and reliability of the ferroelectric film FE. In addition, forming the oxygen film IFA due to the movement of the oxygen OX means an increase of the thickness of the paraelectric film between the ferroelectric film FE and the semiconductor substrate SB and, consequently, variations occur about the characteristics of the ferroelectric memory cell. Accordingly, in the semiconductor device of the comparative example, the performance and the t reliability of the semiconductor device may be degraded by diffusion of the oxygen OX from the ferroelectric film FE.

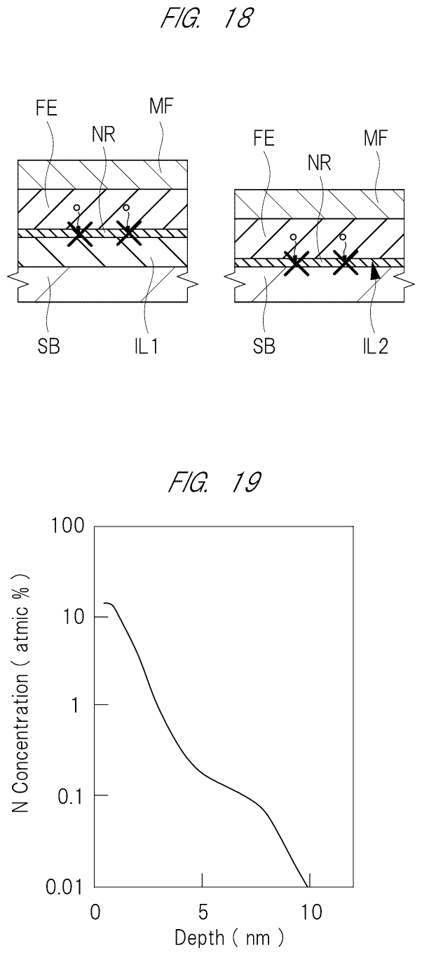

Therefore, in the present embodiment, nitrogen is introduced into each of the paraelectric film IL1 and the paraelectric film IL2. FIG. 18 shows a cross-sectional view of a main part of the semiconductor substrate according to the present embodiment. In addition, FIG. 19 is a graph showing a concentration distribution of nitrogen in a depth direction when nitrogen (N) is introduced into the insulation film by the DNP method.

As shown in FIG. 19, the concentration of nitrogen introduced into the insulation film by the DPN method becomes highest in the vicinity of the upper surface of the insulation film, and decreases toward the lower surface of the insulation film from the upper surface. As shown in FIG. 18, a high concentration region NR into which nitrogen is introduced is formed in the paraelectric film IL1 and the paraelectric film IL2 according to the present embodiment. The high concentration region NR is formed in the vicinity of each upper surface of the paraelectric film IL1 and the paraelectric film IL2. The nitrogen concentration in the paraelectric film IL1 decreases toward the lower surface of the paraelectric film IL1 from the upper surface of the paraelectric film IL1. Here, the thickness of the paraelectric film IL2 is, for example, 1 nm or more and 2 nm or less. For this reason, the nitrogen concentration in the paraelectric film IL2 does not decrease toward the lower surface of the paraelectric film IL2, and only the high concentration region NR is formed. However, the nitrogen in the paraelectric film IL2 may decrease toward the lower surface of the paraelectric film IL2 from the upper surface of the paraelectric film IL2. Nitrogen is introduced at the same condition with respect to the upper surfaces of the paraelectric film IL1 and the paraelectric film IL2, and the thickness of the paraelectric film IL2 is smaller than the thickness of the paraelectric film IL1. For this reason, the nitrogen concentration in the paraelectric film IL1 in the vicinity of the lower surface of the paraelectric film IL1 is smaller than the nitrogen concentration in the paraelectric film IL2 in the vicinity of the lower surface of the paraelectric film IL2.

In the present embodiment, by introducing nitrogen into each of the paraelectric film IL1 and the paraelectric film IL2, the oxygen Ox in the ferroelectric film FE is prevented from diffusing into each of the paraelectric film IL1 and the paraelectric film IL2. Particularly, by forming the high concentration region NR containing nitrogen in the vicinity of each upper surface of the paraelectric film IL1 and the paraelectric film IL2, the high concentration region NR becomes a barrier to the movement of oxygen OX, and can effectively prevent the diffusion of the oxygen OX. Accordingly, the thickness of the paraelectric film due to the diffusion of the oxygen OX is prevented from increasing. As a result, the variations in the characteristics of the ferroelectric memory cell MC is prevented. In addition, since the occurrence of the oxygen vacancy OH is prevented, the characteristics of the ferroelectric film FE can be stabilized. Therefore, the performance and the reliability of the semiconductor device can be improved.

In the present embodiment, nitrogen is introduced into the paraelectric film IL2, and the increase of thickness of the paraelectric film IL2 is prevented, so that the threshold voltage of the memory transistor MQ can be reduced. As a result, the current characteristics of the memory transistor MQ can be improved.

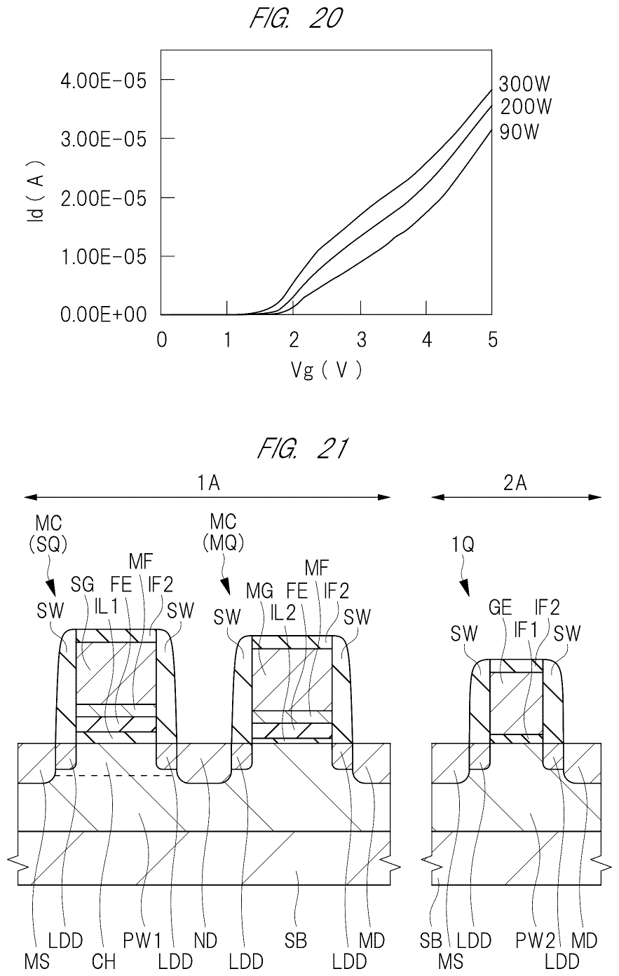

FIG. 20 is a graph showing current voltage characteristics of a memory transistor. A horizontal axis of the graph shown by FIG. 20 indicates a voltage applied to the memory gate electrode MG, and a vertical axis indicates a current flowing in the ferroelectric memory cell MC. FIG. 20 shows a graph when the power used for the DPN method in introducing nitrogen into the paraelectric film IL1 and the paraelectric film IL2 is 90 W, 200 W, and 300 W. as shown in FIG. 20, by increasing the power used for the plasma nitriding, the current voltage characteristics of the memory transistor MQ can be improved.

In addition, the thickness of the paraelectric film IL1 is larger than the thickness of the paraelectric film IL2, so that the influence to the characteristics of the selection transistor SQ due to the introduction of nitrogen is small. When the nitrogen introduced into the paraelectric film IL1 reaches at the upper surface of the semiconductor substrate SB, damages or defects occur on the upper surface of the semiconductor substrate SB, and electrons are scattered and the mobility of the electrons degrades. As a result, an on current of the selection transistor SQ may become small. In the present embodiment, the thickness of the paraelectric film IL1 is larger than the thickness of the paraelectric film IL2, so that the nitrogen introduced into the paraelectric film IL1 is prevented from reaching at the upper surface of the semiconductor substrate SB. Therefore, the decrease in the current characteristics of the selection transistor SQ is prevented. In contrast, the current flowing in the memory transistor MQ is smaller than the current flowing in the selection transistor SQ, so that the influence to the current characteristics of the memory transistor SQ due to the nitrogen introduced in the paraelectric film IL2 is small.

### Modification Example

In the present embodiment, as shown in FIG. 2, forming the channel region CH under the memory gate electrode MG has been explained, but the channel region CH may not be formed.

FIG. 21 shows a cross-sectional view of a semiconductor device according a to modification example. The semiconductor device according to the modification example has the channel region CH formed under the selection gate electrode SG, while the modification example is different from the present embodiment in that the channel region CH is not formed under the memory gate electrode MG. here, the channel region CH is not formed also in the semiconductor substrate SB in the region 2A. Therefore, the impurity concentration of a portion located directly under the selection gate electrode SG in the semiconductor substrate SB is higher than the impurity concentration of a portion located directly under the memory gate electrode MG in the semiconductor substrate SB. In other words, the impurity concentration in the channel region CH is higher than the impurity concentration located directly under the second lamination body in the well region PW1 and located between the source region MS and the drain region MD.

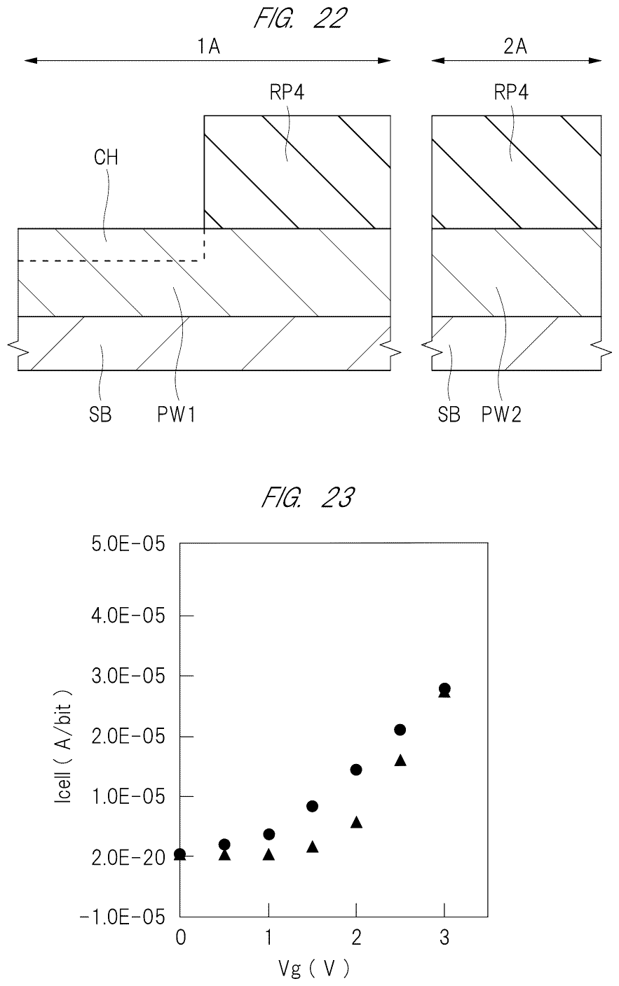

FIG. 22 is a cross-sectional view during a manufacturing step of the semiconductor device according to the modification example of the embodiment. A step shown by FIG. 22 corresponds to a forming step of the channel region CH in the step explained by using FIG. 5. In a manufacturing step of the semiconductor device of the modification example, after the step showed by using FIG. 5, as shown in FIG. 22, a resist pattern PR4 that covers the semiconductor substrate SB in the region 2A and that opens a portion of the region 1A is formed. Here, the portion of the region 1A in which the resist pattern PR4 opens is a region in which the selection transistor SQ is to be formed later. In addition, another portion of the region 1A covered with the resist pattern PR4 is a region in which the memory transistor MQ is to be formed later. Further, here, the resist pattern RP4 also covers the semiconductor substrate SB in the region 2A, but the resist pattern RP4 may expose the semiconductor substrate SB in the region 2A.

Next, by using the resist pattern RP4 as a mask, the p-type impurities are introduced into the semiconductor substrate SB by the ion implantation method. Consequently, the channel region CH is formed in the semiconductor substrate SB in the region 1A exposed from the resist pattern RP4. At this time, the channel region CH is not formed in the semiconductor substrate SB covered with the resist pattern RP4 in the region 1A.

Thereafter, the resist pattern RP4 is removed by the ashing process. Next, as explained by using FIG. 6, the gate insulation film IF1 is formed by the thermal oxidation method, and the plasma nitriding is performed to the gate insulation film IF1. A subsequent step is the same as the steps explained by using FIG. 7 to FIG. 17. In the step explained by using FIG. 9, the paraelectric film IL1 is formed on the channel region CH, and the paraelectric film IL2 is formed on the well region PW1 so as not to overlap with the channel region CH. Consequently, the ferroelectric memory cell MC shown by FIG. 21 can be manufactured. That is, the memory transistor MQ having no channel region CH can be formed.

In the memory transistor of the ferroelectric memory cell, electrons can be trapped in an interface between the ferroelectric film and the metal film on the ferroelectric film. It is conserved that, for example, the threshold voltage of the memory transistor is larger than the threshold voltage of the low breakdown voltage MOSFET formed in the circuit region C1 (see FIG. 1) and the amount of electrons in the semiconductor substrate SB is smaller than a case in which the memory transistor has the channel region. In such a state, the electrons in the semiconductor substrate SB are trapped in the ferroelectric film, so that the mobility of the electrons in the semiconductor substrate drops. Namely, charges of the channel of the memory transistor decrease, and it is different for the current to flow.

Here, regardless of forming the channel region under the memory gate electrode, the influence to a polarization state and a trap charge density in the ferroelectric film of the memory transistor is nothing. Namely, the polarization state and the trap charge density in the ferroelectric film of the memory transistor is not influenced from both of gratitude of a dose amount of the p-type of impurities and the threshold voltage of the memory transistor with respect to the channel region.

Accordingly, by reducing the dose amount of the p-type impurities, the threshold voltage of the memory transistor can be reduced without changing the polarization state and the trap charge density in the ferroelectric film. That is, when the dose amount of the p-type impurities is reduced, an inversion charge density in the semiconductor substrate increases.

In the present modification example, by not forming the channel region CH of the memory transistor MQ, the threshold voltage of the memory transistor MQ can be reduced. Consequently, the current characteristics of the memory transistor can be improved. In comparison with a case if forming the channel region CH, the amount of the electrons in the semiconductor substrate SB is large in the present modification example, so that even if the electrons in the ferroelectric film FE is trapped due to the polarization, the high mobility of the electrons can be realized.

FIG. 23 a is graph showing current voltage characteristics of the memory transistor in which channel dose is performed. FIG. 24 is a graph showing current voltage characteristics of the memory transistor in which no channel dose is performed. A horizontal axis of each graph of FIG. 23 and FIG. 24 indicates a gate voltage applied to the memory gate electrode MG, and a vertical axis indicates a current flowing in the ferroelectric memory cell MC. In FIG. 23 and FIG. 24, an off current is i illustrated by triangle plots, and an on current is illustrated by round plots. The respective plots illustrated in FIG. 23 and FIG. 24 show data measured by the condition that the gate length, the gate width, and the drain voltage are the same. In comparison with FIG. 23 and FIG. 24, it is found that when the channel region CH is not formed without performing channel dose, the on current increases.

Accordingly, in the present modification example, a threshold voltage of the memory transistor is reduced, thereby making the memory transistor lower resistance. Consequently, the current characteristics of the memory transistor can be improved.

In addition, in the present modification example, presence or absence of the channel region CH of the memory transistor MQ is not influenced to the characteristics of the selection transistor SQ. Namely, in the present modification example, the influence to the characteristics of the selection transistor is suppressed and, simultaneously, the characteristics of the memory transistor MQ can be improved.

As described above, the present invention has been explained based on the embodiments for making the present invention, but the present invention is not limited to the above embodiments and can be variously modified within a range not departing from the gist.

For, in FIG. 17, the channel region, the source region, and the drain region are formed in the semiconductor substrate in the region 2A. In contrast, a Silicon On Insulator (SOI) substrate having the semiconductor substrate as a substrate, a buried oxide film formed on the substrate, and the semiconductor layer formed on the buried oxide film may be used. When the SOI substrate is used, the channel region, the source region, and the drain region in the region 2A are formed in the semiconductor layer of the SOI substrate.

In addition, in the above embodiment, a case of the memory transistor and the low breakdown voltage MOSFET are n-channel-type MOSFETs has been explained. Unlike this, each MOSFET may be a p-channel type.

What is claimed is:

1. A semiconductor device comprising:
a semiconductor substrate;
a first source region of a first conductivity type, the first source region being formed in the semiconductor substrate;
a first drain region of the first conductivity type, the first drain region being formed in the semiconductor substrate;
a first lamination body formed on the semiconductor substrate and arranged between the first source region and the drain region in plan view; and
a second lamination body formed on the semiconductor substrate and arranged between the first source region and the first drain region in plan view,
wherein the first lamination body has:
a first paraelectric film formed on the semiconductor substrate;
a first ferroelectric film formed on the first paraelectric film; and
a first gate electrode formed on the first ferroelectric film,
wherein the second lamination body has:
a second paraelectric film formed on the semiconductor substrate;
a second ferroelectric film formed on the second paraelectric film; and
a second gate electrode formed on the second ferroelectric film,
wherein the first lamination body, the second lamination body, the first source region, and the first drain region configure a non-volatile memory cell,
wherein a thickness of the first paraelectric film is larger than a thickness of the second paraelectric film,
wherein each of the first paraelectric film and the second paraelectric film contain nitrogen, and
wherein a nitrogen concentration in the first paraelectric film decreases toward a lower surface of the first paraelectric film from an upper surface of the first paraelectric film.

2. The semiconductor device according to claim 1,
wherein each of the first paraelectric film and the second paraelectric film is a silicon oxide film containing nitrogen.

3. The semiconductor device according to claim 1, further comprising:
a first semiconductor region of a second conductivity type different from the first conductivity type, the first semiconductor region being formed in the semiconductor substrate; and
a second semiconductor region of the second conductivity type, the second semiconductor region being arranged between the first source region and the first drain region, located directly under the first lamination body, and having a predetermined depth from an upper surface of the first semiconductor region,
wherein the first source region and the first drain region are formed in the first semiconductor region, and
wherein an impurity concentration in the second semiconductor region is higher than an impurity concentration in a portion of the first semiconductor region located directly under the second lamination body and located between the first source region and the first drain region.

4. The semiconductor device according to claim 1, further comprising:
a second source region formed in the semiconductor substrate;
a second drain region formed in the semiconductor substrate;
a gate insulation film formed on the semiconductor substrate and arranged between the second source region and the second drain region in plan view; and
a third gate electrode formed on the gate insulation film,
wherein the second source region, the second drain region, the gate insulation film, and the third gate electrode configure a transistor,
wherein the gate insulation film contains nitrogen, and
wherein a nitrogen concentration in the gate insulation film is lower than a nitrogen concentration in the second paraelectric film.

5. The semiconductor device according to claim 1,
wherein each of the first ferroelectric film and the second ferroelectric film contains hafnium oxide.

6. A method of manufacturing a semiconductor device, the method comprising:
(a) forming a first paraelectric film on a semiconductor substrate;
(b) after the (a), forming a second paraelectric film on the semiconductor substrate, the second paraelectric film having a thickness smaller than a thickness of the first paraelectric film;
(c) introducing nitrogen into each of the first paraelectric film and the second paraelectric film by using a plasma nitriding method;
(d) forming a first ferroelectric film and a first gate electrode on the first paraelectric film in order, and forming a second ferroelectric film and a second gate electrode on the second paraelectric film in order; and
(e) forming a first source region of a first conductivity type and a first drain region of the first conductivity type in the semiconductor substrate so that the first gate electrode and the second gate electrode are arranged between the first source region and the first drain region in plan view.

7. The method according to claim 6,
wherein a nitrogen concentration in the first paraelectric film decreases toward a lower surface of the first paraelectric film from an upper surface of the first paraelectric film.

8. The method according to claim 6,
wherein each of the first paraelectric film and the second paraelectric film is a silicon oxide film containing nitrogen.

9. The method according to claim 6, further comprising:
(a1) before the (a), forming a first semiconductor region of a second conductivity type different from the first conductivity type in the semiconductor substrate;
(a2) before the (a), forming a second semiconductor region of the second conductivity type in the first semiconductor region in a state in which a portion of the semiconductor substrate at which the second paraelectric film is formed is covered with a protection film, the second semiconductor region having higher in impurity concentration than the first semiconductor region; and
(a3) before the (a), removing the protection film,
wherein in the (a), the first paraelectric film is formed on the second semiconductor region,
wherein in the (b), the second paraelectric film is formed on the first semiconductor region so as not to overlap with the second semiconductor region, and
wherein in the (e), the first source region and the first drain region are formed in the first semiconductor region.

10. The method according to claim 6, further comprising:
(a4) before the (a), forming an insulation film on the semiconductor substrate; and
(a5) before the (a), introducing nitrogen into the insulation film by using a plasma nitriding method,
wherein power used for the plasma nitriding method in the (a5) is lower than power used for the plasma nitriding method in the (c).

11. The method according to claim 10,
wherein in the (d), a third gate electrode is formed on the insulation film, and
wherein in the (e), a second source region of the first conductivity type and a second drain region of the first conductivity type are formed in the semiconductor substrate so that the third gate electrode is arranged between the second source region and the second drain region in plan view.

12. The method according to claim 6,
wherein each of the first ferroelectric film and the second ferroelectric film contains hafnium oxide.
